(19) United States
(12) Patent Application Publication
(10) Pub. No.: US 2024/0223157 A1
(43) Pub. Date: Jul. 4, 2024

(54) ACOUSTIC WAVE FILTER DEVICE AND MULTIPLEXER

(71) Applicant: Murata Manufacturing Co., Ltd., Nagaokakyo-shi (JP)

(72) Inventor: Kenichi UESAKA, Nagaokakyo-shi (JP)

(21) Appl. No.: 18/607,633

(22) Filed: Mar. 18, 2024

Related U.S. Application Data
(63) Continuation of application No. PCT/JP2022/035820, filed on Sep. 27, 2022.

(30) Foreign Application Priority Data
Sep. 29, 2021 (JP) 2021-159713

(51) Int. Cl. H03H 9/145; H03H 9/02; H03H 9/64

(52) U.S. Cl. CPC H03H 9/14541; H03H 9/02661; H03H 9/6483

(57) ABSTRACT

An acoustic wave filter device includes series arm resonators and parallel arm resonators. A parallel arm resonator that has the highest resonant frequency has a reflector wavelength that is the same or substantially the same as an IDT wavelength and has an IDT-reflector gap that is about 0.5 times the reflector wavelength. The remaining parallel arm resonators each have a reflector wavelength longer than the IDT wavelength and have an IDT-reflector gap shorter than about 0.5 times the reflector wavelength.

### CROSS REFERENCE TO RELATED APPLICATIONS

This application claims the benefit of priority to Japanese Patent Application No. 2021-159713 filed on Sep. 29, 2021 and is a Continuation Application of PCT Application No. PCT/JP2022/035820 filed on Sep. 27, 2022. The entire contents of each application are hereby incorporated herein by reference.

### BACKGROUND OF THE INVENTION

### 1. Field of the Invention

The present disclosure relates to acoustic wave filter devices and multiplexers.

### 2. Description of the Related Art

In recent years, multiband systems have been used to improve the data transmission speed of mobile phones. In this case, since transmission and reception in a plurality of frequency bands are performed on occasions, a plurality of filter devices allowing radio frequency signals in different frequency bands to pass therethrough are disposed in the front end circuit of a mobile phone. In this case, since a mounting space provided for the front end circuit described above is limited, the plurality of filter devices are required to be downsized and have high isolation from the neighboring and low loss in the pass bands.

International Publication No. 2018/168836 discloses the configuration of a surface acoustic wave device that provides transmission characteristics. More specifically, the surface acoustic wave device has a circuit configuration including a plurality of surface acoustic wave resonators each having an IDT electrode and reflectors. Table 7 in International Publication No. 2018/168836 illustrates an example in which a distance between the centers of one of electrode fingers of the reflector that is closest to the IDT electrode and one of electrode fingers of the IDT electrode that is closest to one of the reflectors is smaller than or equal to 0.5 times an IDT wavelength and in which a reflector wavelength is longer than the IDT wavelength.

In the surface acoustic wave device described in International Publication No. 2018/168836, it is possible to shift an unwanted response occurring on the higher-frequency side of the pass band of the acoustic wave filter device toward a further higher frequency. However, the attenuation characteristic on the lower-frequency side of the pass band varies largely on occasions.

### SUMMARY OF THE INVENTION

Example embodiments of the present invention provide acoustic wave filter devices that each enable an attenuation characteristic on a lower-frequency side of a pass band of the acoustic wave filter devices to be prevented from varying largely.

An acoustic wave filter device according to an example embodiment of the present invention includes a plurality of acoustic wave resonators. Each of the plurality of acoustic wave resonators includes a series arm resonator located on a first path connecting two input/output terminals and a plurality of parallel arm resonators connected between the first path and ground. Each of the plurality of parallel arm resonators is provided on a piezoelectric substrate and each includes an IDT electrode including a pair of comb-shaped electrodes facing each other and a reflector adjacent to the IDT electrode in an acoustic wave propagation direction. Each of the comb-shaped electrodes of the pair of comb-shaped electrodes includes a plurality of electrode fingers extending in a direction that crosses the acoustic wave propagation direction and a busbar electrode that connects ends of the plurality of electrode fingers to each other. The reflector includes a plurality of reflective electrode fingers extending in the direction that crosses the acoustic wave propagation direction. In a case where a reflector wavelength is twice a pitch of the plurality of reflective electrode fingers, where an IDT wavelength is twice a pitch of the plurality of electrode fingers included in the IDT electrode, and where an IDT-reflector gap is a center-to-center distance, in the acoustic wave propagation direction, between an electrode finger of the plurality of electrode fingers that is closest to the reflector and a reflective electrode finger of the plurality of reflective electrode fingers that is closest to the IDT electrode, a parallel arm resonator of the plurality of parallel arm resonators with a highest resonant frequency has a reflector wavelength the same or substantially the same as the IDT wavelength and has an IDT-reflector gap that is about 0.5 times the reflector wavelength, and among the plurality of parallel arm resonators, at least one of one or more remaining parallel arm resonators except the parallel arm resonator with the highest resonant frequency has a reflector wavelength longer than the IDT wavelength and has an IDT-reflector gap that is shorter than about 0.5 times the reflector wavelength.

An acoustic wave filter device according to an example embodiment of the present invention includes a plurality of acoustic wave resonators. Each of the plurality of acoustic wave resonators includes a series arm resonator located on a first path connecting two input/output terminals and a plurality of parallel arm resonators connected between the first path and ground. Each of the plurality of parallel arm resonators is provided on a piezoelectric substrate and includes an IDT electrode including a pair of comb-shaped electrodes facing each other and a reflector adjacent to the IDT electrode in an acoustic wave propagation direction. Each of the comb-shaped electrodes of the pair of comb-shaped electrodes includes a plurality of electrode fingers extending in a direction that crosses the acoustic wave propagation direction and a busbar electrode that connects ends of the plurality of electrode fingers to each other. The reflector includes a plurality of reflective electrode fingers extending in the direction that crosses the acoustic wave propagation direction. In a case where an electrode finger pitch is a pitch of the plurality of electrode fingers included in the IDT electrode, where a reflective electrode finger pitch is a pitch of the plurality of reflective electrode fingers, and where an IDT-reflector gap is a center-to-center distance, in the acoustic wave propagation direction, between an electrode finger of the plurality of electrode fingers that is closest to the reflector and a reflective electrode finger of the plurality of reflective electrode fingers that is closest to the IDT electrode, a parallel arm resonator of the plurality of parallel arm resonators that has a shortest electrode finger pitch has a reflective electrode finger pitch the same or substantially the same as the electrode finger pitch and has an IDT-reflector gap that is the same or substantially the same as the reflective electrode finger pitch, and among the plurality of parallel arm resonators, at least one of one or more remaining parallel arm resonators except the parallel arm resonator with a shortest electrode finger pitch has a reflective electrode finger pitch longer than the electrode finger pitch and has an IDT-reflector gap that is shorter than the reflective electrode finger pitch.

A multiplexer according to an example embodiment of the present invention includes a plurality of filters including an acoustic wave filter device according to an example embodiment of the present invention. An input/output terminal of each of the plurality of filters is directly or indirectly connected to a common terminal. Among the plurality of filters, at least one of one or more remaining filters except the acoustic wave filter device has a pass band lower than a frequency in a pass band of the acoustic wave filter device.

A multiplexer according to an example embodiment of the present invention includes a plurality of filters including an acoustic wave filter device according to an example embodiment of the present invention. An input/output terminal of each of the plurality of filters is directly or indirectly connected to a common terminal. Among the plurality of filters, at least one of one or more remaining filters except the acoustic wave filter device has a pass band higher than a frequency in a pass band of the acoustic wave filter device.

The acoustic wave filter devices according to example embodiments of the present invention each enable the attenuation characteristic on the lower-frequency side of the pass band to be prevented from varying largely.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a view illustrating the circuit configuration of an acoustic wave filter device according to Example Embodiment 1 of the present invention.

FIG. 2 illustrates a plan view and a cross-sectional view schematically illustrating the electrode configuration of an acoustic wave resonator included in the acoustic wave filter device.

FIG. 3 illustrates tables of electrode parameters for series arm resonators and parallel arm resonators of the acoustic wave filter device according to Example Embodiment 1 of the present invention.

FIG. 4 illustrates graphs of the impedance characteristics of parallel arm resonators in Example Embodiment 1 of the present invention and Comparative Example.

FIG. 5 is a graph illustrating the respective return losses of the parallel arm resonators in Example Embodiment 1 of the present invention and Comparative Example.

FIG. 6 is a graph illustrating the bandpass characteristics of the acoustic wave filter devices in Example Embodiment 1 of the present invention and Comparative Example.

FIG. 7 is a graph in which a portion of the bandpass characteristics illustrated in FIG. 6 is enlarged.

FIG. 8 is a graph illustrating the bandpass characteristics of the acoustic wave filter device in a case where the electrode fingers of the IDT electrode have different widths in Comparative Example.

FIG. 9 is a graph illustrating the bandpass characteristics of the acoustic wave filter device in a case where the electrode fingers of the IDT electrode have different widths in Example Embodiment 1 of the present invention.

FIG. 10 is a circuit configuration diagram of a multiplexer according to Example Embodiment 2 of the present invention and a peripheral circuit thereof.

### DETAILED DESCRIPTION OF THE EXAMPLE EMBODIMENTS

Example embodiments of the present invention will be described in detail with reference to the drawings and the tables. Example embodiments to be described later represent comprehensive or specific examples. Accordingly, a numerical value, a shape, a material, a component, an arrangement of the component, connection configurations, and the like described in the following example embodiments are examples and are not intended to limit the present invention. Among components in the following example embodiments, a component that is not described in an independent claim is described as an optional component. The sizes and the ratio of the sizes of components in the drawings are not necessarily precisely illustrated.

### Example Embodiment 1

### Schematic Configuration of Acoustic Wave Filter Device

The schematic configuration of an acoustic wave filter device 1 according to Example Embodiment 1 of the present invention will be described.

First, the basic operation principle of a ladder acoustic wave filter device including series arm resonators and parallel arm resonators is described. Each parallel arm resonator has a resonant frequency frp at which impedance |Z| becomes minimum and an anti-resonant frequency fap (>frp) at which the impedance |Z| becomes maximum. Each series arm resonator has a resonant frequency frs at which the impedance | Z| becomes minimum and an anti-resonant frequency fas (>frs>frp) at which the impedance |Z| becomes maximum. In configuring a band pass filter by using the ladder resonators, the anti-resonant frequency fap of the parallel arm resonator and the resonant frequency frs of the series arm resonator are close to each other. An area near the resonant frequency frp where the impedance of the parallel arm resonator approaches zero thus becomes a lower-frequency-side block area. In addition, a frequency made higher causes the impedance of the parallel arm resonator to be increased in an area near the anti-resonant frequency fap and the impedance of the series arm resonator to approach zero in an area near the resonant frequency frs. An area near the anti-resonant frequency fap to the resonant frequency frs thus becomes a signal passing area. Further, the frequency made higher and close to the anti-resonant frequency fas causes the impedance of the series arm resonator to be increased, and an area thereof becomes a higher-frequency-side block area. Specifically, a pass band is provided based on the anti-resonant frequency fap of the parallel arm resonator and the resonant frequency frs of the series arm, an attenuation pole on the lower-frequency side of the pass band is provided based on the resonant frequency frp of the parallel arm resonator, and an attenuation pole on a higher-frequency side of the pass band is provided based on the anti-resonant frequency fas of the series arm resonator.

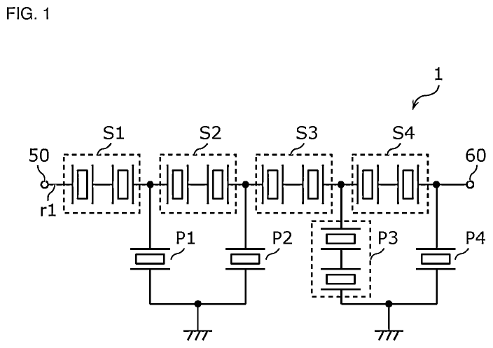

FIG. 1 is a view illustrating the circuit configuration of the acoustic wave filter device 1 according to Example Embodiment 1.

As illustrated in FIG. 1, the acoustic wave filter device 1 includes series arm resonators S1, S2, S3, and S4, parallel arm resonators P1, P2, P3, and P4, and input/output terminals 50 and 60.

The series arm resonators S1 to S4 are connected in series on a first path rl connecting the input/output terminal 50 and the input/output terminal 60. The parallel arm resonators P1 to P4 are connected between the first path rl and the ground (a reference terminal). The series arm resonators S1 to S4 each include two divided resonators connected in series to each other. The parallel arm resonator P3 includes two divided resonators connected in series to each other.

With the connection configuration described above of the series arm resonators S1 to S4 and the parallel arm resonators P1 to P4, the acoustic wave filter device 1 is configured as a ladder band pass filter. The circuit configuration illustrated in FIG. 1 is an example thereof, and the number of series arm resonators, the number of parallel arm resonators, or the like is not limited to that in the configuration in FIG. 1.

### Acoustic Wave Resonator Structure

The structure of an acoustic wave resonator 10 included in the acoustic wave filter device 1 will now be described. The series arm resonators S1 to S4 and the parallel arm resonators P1 to P4 that are described above have the same or substantially the same structure as that of the acoustic wave resonator 10.

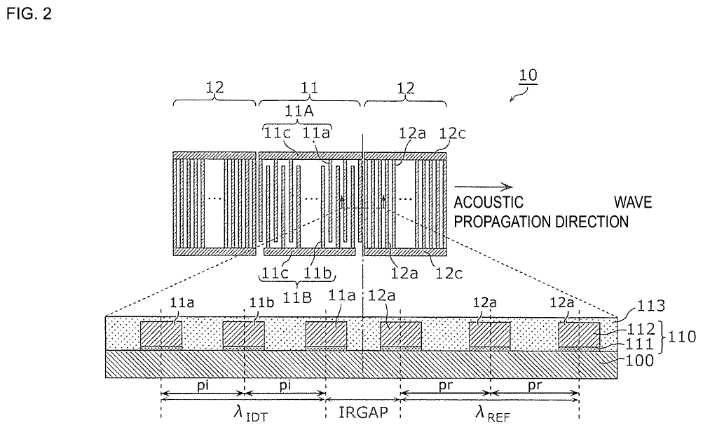

FIG. 2 illustrates a plan view and a cross-sectional view schematically illustrating the electrode configuration of the acoustic wave resonator 10 included in the acoustic wave filter device 1.

The acoustic wave resonator 10 illustrated in FIG. 2 includes a piezoelectric substrate 100, an electrode 110, and a protective film 113 and includes an interdigital transducer (IDT) electrode 11 including these components and reflectors 12. The acoustic wave resonator 10 according to the present example embodiment is, for example, a surface acoustic wave (SAW) resonator including the IDT electrode 11, the reflectors 12, and the piezoelectric substrate 100.

The acoustic wave resonator 10 illustrated in FIG. 2 is provided to describe the typical structure thereof, and the number of electrode fingers of an electrode, the length thereof, or the like is not limited to this.

The electrode 110 of the IDT electrode 11 and the reflectors 12 include a layered structure including a close-contact layer 111 and a main electrode layer 112 that are laminated, as illustrated in the cross-sectional view in FIG. 2.

The close-contact layer 111 improves close contact between the piezoelectric substrate 100 and the main electrode layer 112, and for example, Ti is used as a material thereof.

As a material of the main electrode layer 112, for example, Al including about 1% Cu is used.

The protective film 113 covers the electrode 110. The protective film 113 protects the main electrode layer 112 from an external environment, controls a frequency temperature characteristic, increases anti-humidity, and the like and is a film including, for example, silicon dioxide (SiO) as a main component.

The materials of the close-contact layer 111, the main electrode layer 112, and the protective film 113 are not limited to the materials described above. Further, the electrode 110 does not have to have the layered structure described above. The electrode 110 may be made of a metal such as, for example, Ti, Al, Cu, Pt, Au, Ag, or Pd, or an alloy thereof and may also include a plurality of multilayer bodies made of the metal or the alloy above. The protective film 113 does not have to be provided.

The piezoelectric substrate 100 is made of, for example, θ° rotated Y cut X SAW propagation LiNbO3 piezoelectric single crystal or a piezoelectric ceramic (lithium niobate single crystal or ceramic that is cut along a plane with a normal line serving as an axis rotated by θ° in a z axis direction from a Y axis with respect to an X axis serving as the center axis and in which a surface acoustic wave propagates in the X-axis direction).

The piezoelectric substrate 100 may be a substrate including a piezoelectric layer in at least portion thereof and may also have a layered structure including the piezoelectric layer. The piezoelectric substrate 100 may include, for example, a high-acoustic-velocity support substrate, a low-acoustic-velocity film, and a piezoelectric layer and may include the high-acoustic-velocity support substrate, the low-acoustic-velocity film, and the piezoelectric layer that are stacked in this order.

As illustrated in a plan view in FIG. 2, the IDT electrode 11 includes a pair of comb-shaped electrodes 11A and 11B facing each other. The comb-shaped electrode 11A includes a plurality of electrode fingers 11a extending in a direction that crosses an acoustic wave propagation direction and one of busbar electrodes 11c that connects ends of the plurality of electrode fingers 11a to each other. The comb-shaped electrode 11B includes a plurality of electrode fingers 11b extending in the direction that crosses the acoustic wave propagation direction and the other one of the busbar electrodes 11c that connects ends of the plurality of electrode fingers 11b. The plurality of electrode fingers 11a and 11b are each alternately disposed in the acoustic wave propagation direction. The acoustic wave propagation direction is a direction that crosses a direction in which the electrode fingers 11a and 11b extend and is, in this example, a direction orthogonal or substantially orthogonal to the direction in which the electrode fingers 11a and 11b extend.

Each reflector 12 is adjacent to the IDT electrode 11 in the acoustic wave propagation direction. The reflector 12 includes a plurality of electrode fingers extending in the direction that crosses the acoustic wave propagation direction and a busbar electrode that connects ends of the plurality of electrode fingers to each other. In this specification, electrode fingers of a reflector are referred to as reflective electrode fingers. The plurality of reflectors 12 are provided, and each of the paired reflectors 12 is disposed on a corresponding outer sides of the IDT electrode 11 in the acoustic wave propagation direction.

As illustrated in FIG. 2, in an area between the IDT electrode 11 and each reflector 12, a distance, in the acoustic wave propagation direction, between the center of one of the plurality of electrode fingers 11a and 11b that is closest to the reflector 12 (for example, 11a) and the center of one of a plurality of reflective electrode fingers 12a that is closest to the IDT electrode 11 (hereinafter, the distance, in the acoustic wave propagation direction, between the centers of the two electrode fingers is simply referred to as a center-to-center distance on occasions) is defined as an IDT-reflector gap (IRGAP). A length twice an electrode finger pitch pi that is the pitch of the plurality of electrode fingers 11a and 11b included in the IDT electrode 11 is defined as an IDT wavelength (λ_{IDT}). A pitch twice a reflective electrode finger pitch pr that is the pitch of the plurality of reflective electrode fingers 12a is defined as a reflector wavelength (λ_{REF}).

The electrode finger pitch pi is a center-to-center distance between one of the electrode fingers 11a and one of the electrode fingers 11b that are adjacent to each other in the acoustic wave propagation direction, among the plurality of electrode fingers 11a and 11b included in the IDT electrode 11. The pitches of the plurality of electrode fingers 11a and 11b in the IDT electrode 11 may all be the same or may partially or all be different.

The electrode finger pitch pi may be derived in the following manner. For example, the total number of electrode fingers of the electrode fingers 11a and 11b included in the IDT electrode 11 is Ni. A center-to-center distance, in the acoustic wave propagation direction, between an electrode finger located at one end of the IDT electrode 11 and an electrode finger located at the other end is Di. The electrode finger pitch pi can then be expressed by the equation pi=Di/(Ni−1). It can also be said that (Ni−1) is the total number of gaps between neighboring electrode fingers in the IDT electrode 11.

If the acoustic wave resonator 10 includes a plurality of divided resonators, the electrode finger pitch pi is determined in such a manner that the total value of center-to-center distances between electrode fingers located at both of ends of an IDT electrode included in each divided resonator in the acoustic wave propagation direction is divided by the total value of the total number of gaps between neighboring electrode fingers in the IDT electrode.

The reflective electrode finger pitch pr is a center-to-center distance between the reflective electrode fingers 12a adjacent to each other in the acoustic wave propagation direction, among the plurality of reflective electrode fingers 12a included in the reflector 12. The pitches of the plurality of reflective electrode fingers 12a in the reflector 12 may all be the same or may partially or all be different.

The reflective electrode finger pitch pr may be derived in the following manner. For example, the total number of electrode fingers of the reflective electrode fingers 12a included in the reflector 12 is Nr. A center-to-center distance, in the acoustic wave propagation direction, between a reflective electrode finger located at one end of the reflector 12 and a reflective electrode finger located at the other end is Dr. The reflective electrode finger pitch pr can then be expressed by the equation pr=Dr/(Nr−1). It can also be said that (Nr−1) is the total number of gaps between neighboring reflective electrode fingers in the reflector 12.

Relationship among Plurality of Parallel Arm Resonators

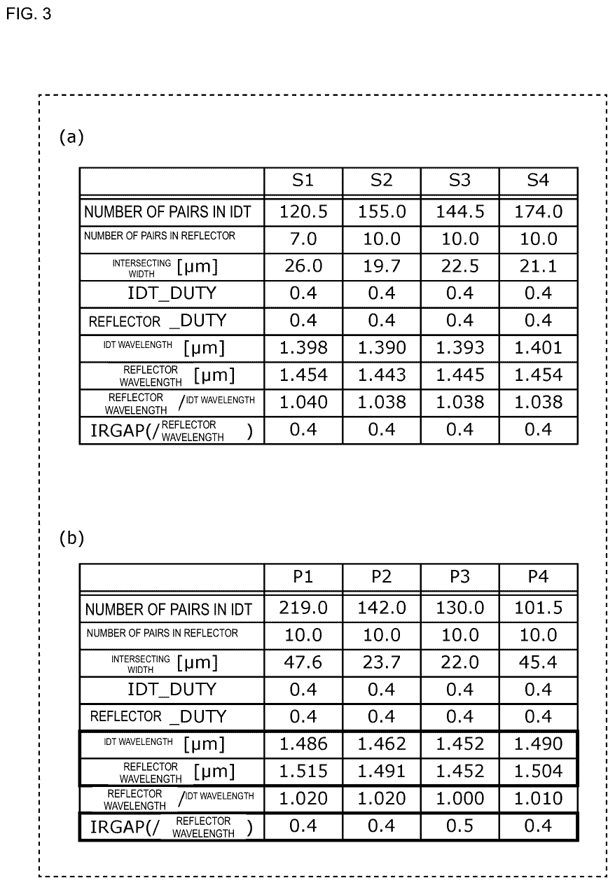

FIG. 3 illustrates tables of electrode parameters for the series arm resonators S1 to S4 and the parallel arm resonators P1 to P4 of the acoustic wave filter device 1. In (a) in FIG. 3, the IDT wavelengths Δ_{IDT}, the reflector wavelengths Δ_{REF}, the IDT-reflector gaps IRGAP, and the like of the series arm resonators S1 to S4 are illustrated. In (b) in FIG. 3, the IDT wavelengths Δ_{IDT}, the reflector wavelengths Δ_{REF}, the IDT-reflector gaps IRGAP, and the like of the parallel arm resonators P1 to P4 are illustrated.

In the example illustrated in (b) in FIG. 3, the parallel arm resonator P3 of the plurality of parallel arm resonators P1 to P4 has the shortest IDT wavelength Δ_{IDT}. That is, in this example, the parallel arm resonator P3 of the plurality of parallel arm resonators P1 to P4 has the highest resonant frequency frp. The resonant frequency frp is increased, for example, not only by making the electrode finger pitch pi shorter as in the present example embodiment by also by making the width of the electrode fingers 11a and 11b narrower, by making the film thickness of the electrode fingers 11a and 11b thinner, or by changing the thickness of the protective film 113 on the electrode fingers 11a and 11b.

In the parallel arm resonator P3 with the highest resonant frequency frp, the reflector wavelength Δ_{REF} is the same or substantially the same as the IDT wavelength Δ_{IDT}, the IDT-reflector gap IRGAP is about 0.5 times the reflector wavelength Δ_{REF} (Δ_{REF}=Δ_{IDT}, and IRGAP=0.5×Δ_{REF}). The phrase “the reflector wavelength Δ_{REF} is the same as the IDT wavelength Δ_{IDT}” in the present example embodiment denotes that the values of both the value of the reflector wavelength Δ_{REF} and the value of the IDT wavelength Δ_{IDT} match up to at least three significant digits. The phrase “the IDT-reflector gap IRGAP is 0.5 times the reflector wavelength Δ_{REF}” denotes that the values of both the value of the IDT-reflector gap IRGAP and the value that is 0.5 times the reflector wavelength Δ_{REF} match up to at least three significant digits.

In contrast, among the plurality of parallel arm resonators P1 to P4, at least one of the remaining parallel arm resonators P1, P2, and P4 except the parallel arm resonator P3 having highest resonant frequency frp has a reflector wavelength Δ_{REF} longer than the IDT wavelength Δ_{IDT} and an IDT-reflector gap IRGAP shorter than about 0.5 times the reflector wavelength Δ_{REF}. Specifically, all of the remaining parallel arm resonators P1, P2, and P4 have the reflector wavelength Δ_{REF} longer than the IDT wavelength Δ_{IDT} and the IDT-reflector gap IRGAP shorter than about 0.5 times the reflector wavelength Δ_{REF} (Δ_{REF}>Δ_{IDT}, and IRGAP<0.5×Δ_{REF}).

When being compared based on a reflector wavelength/IDT wavelength value, for example, the parallel arm resonator P3 has a value of about 1.000, and the parallel arm resonators P1, P2, and P3 have values greater than about 1.000. Specifically, the reflector wavelength/IDT wavelength value of each of the parallel arm resonators P1, P2, and P3 is between about 1.010 and about 1.020, inclusive.

The IDT wavelength Δ_{IDT}, the reflector wavelength AREE and the reflector wavelength/the IDT wavelength value of the plurality of parallel arm resonators P1 to P4 have the relationship described above, and it is possible to reduce or prevent the attenuation characteristic on the lower-frequency side of the pass band in the acoustic wave filter device 1.

The relationship among the plurality of parallel arm resonators P1 to P4 is represented by using the wavelength and the frequency but may be represented by using the pitch of the electrode fingers. For example, the IDT wavelength Δ_{IDT} corresponds to twice the electrode finger pitch pi, the reflector wavelength Δ_{REF} corresponds to twice the reflective electrode finger pitch pr, and the resonant frequency frp is a frequency corresponding to the IDT wavelength Δ_{IDT}. The relationship among the plurality of parallel arm resonators P1 to P4 may also be represented as below.

That is, in the acoustic wave filter device 1, the electrode finger pitch pi of the IDT electrode 11 is the shortest in the parallel arm resonator P3 of the plurality of parallel arm resonators P1 to P4.

The parallel arm resonator P3 having the shortest electrode finger pitch pi has a reflective electrode finger pitch pr that is the same or substantially the same as the electrode finger pitch pi and an IDT-reflector gap IRGAP that is the same or substantially the same as the reflective electrode finger pitch pr (pr=pi, and IRGAP=pr). The phrase “the reflective electrode finger pitch pr is the same as the electrode finger pitch pi” in this example embodiment denotes that the values of both (the value of the reflective electrode finger pitch pr and the value of the electrode finger pitch pi) match up to at least three significant digits. The phrase “the IDT-reflector gap IRGAP is the same as the reflective electrode finger pitch pr” denotes that the values of both (the value of the IDT-reflector gap IRGAP and the value of the reflective electrode finger pitch pr) match up to at least three significant digits.

In contrast, among the plurality of parallel arm resonators P1 to P4, at least one of the remaining parallel arm resonators P1, P2, and P4 except the parallel arm resonator P3 having the shortest electrode finger pitch pi has a reflective electrode finger pitch pr longer than the electrode finger pitch pi and an IDT-reflector gap IRGAP shorter than the reflective electrode finger pitch pr. Specifically, all of the remaining parallel arm resonators P1, P2, and P4 have the reflective electrode finger pitch pr longer than the electrode finger pitch pi and the IDT-reflector gap IRGAP shorter than the reflective electrode finger pitch pr (pr>pi, and IRGAP<pr).

The electrode finger pitch pi, the reflective electrode finger pitch pr, and the IDT-reflector gap IRGAP of the plurality of parallel arm resonators P1 to P4 have the relationship described above, and it is possible to prevent the attenuation characteristic on the lower-frequency side of the pass band from varying largely in the acoustic wave filter device 1.

### Bandpass Characteristics of Acoustic Wave Filter Device and Others

The bandpass characteristic and the like of the acoustic wave filter device 1 having the configuration described above will be described as compared with an acoustic wave filter device in Comparative Example.

The acoustic wave filter device in Comparative Example is different from the acoustic wave filter device 1 in Example Embodiment 1 in electrode parameters for the parallel arm resonator P3. In Comparative Example, all of the parallel arm resonators P1 to P4 including the parallel arm resonator P3 have a reflector wavelength Δ_{REF} longer than the IDT wavelength Δ_{IDT} and an IDT-reflector gap IRGAP shorter than about 0.5 times the reflector wavelength Δ_{REF} (illustration thereof is omitted).

The parallel arm resonators P1, P2, P3, and P4 are resonators the anti-resonant frequency fap of which is present within the pass band of the acoustic wave filter device. That is, the parallel arm resonators P1 to P4 are resonators defining the pass band of a ladder filter, and any parallel arm resonator provided for a purpose other than defining the pass band is not included in the parallel arm resonators P1 to P4 described herein.

Hereinafter, an example where the parallel arm resonator P3 of the plurality of parallel arm resonators P1 to P4 has the highest resonant frequency frp will be described. In addition, a case where the pass band of the acoustic wave filter device is, for example, between about 2595 MHz and about 2722 MHz, inclusive will be described. The pass band is a band in which with respect to the peak value (the smallest value) of insertion loss, the value of the insertion loss stays within about 3 dB from the peak value.

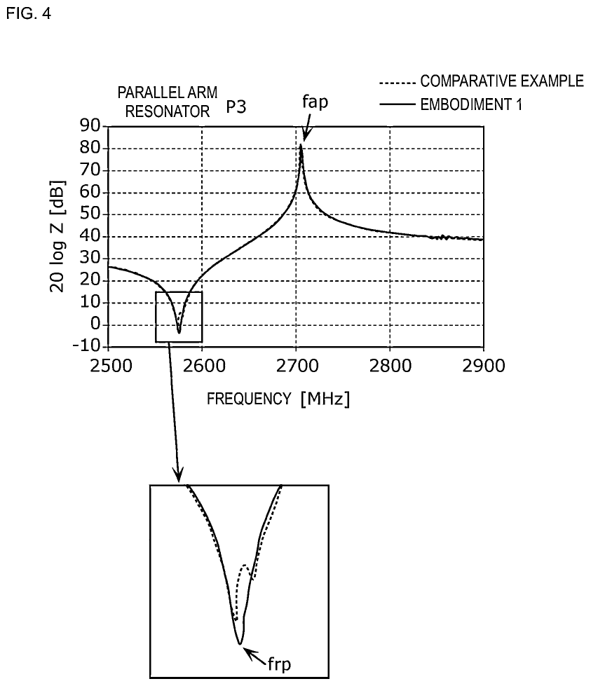

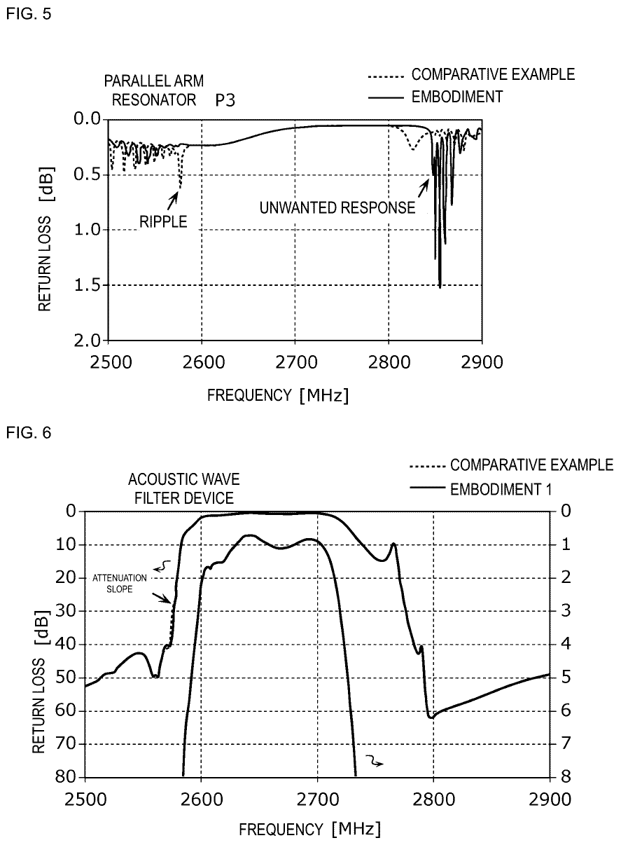

FIG. 4 illustrates of graphs the impedance characteristics of the parallel arm resonators P3 in Example Embodiment 1 and Comparative Example. FIG. 5 is a graph illustrating the respective return losses of the parallel arm resonators P3 in Example Embodiment 1 and Comparative Example.

As illustrated in FIG. 4, in the parallel arm resonator P3 in Comparative Example, a waveform representing the resonant frequency frp distorts between about 2570 MHz and about 2580 MHZ on the lower-frequency side of the pass band, and an impedance value is not sufficiently low. As illustrated in FIG. 5, in the parallel arm resonator P3 in Comparative Example, it is possible to shift an unwanted response occurring on the higher-frequency side of the pass band to a position spaced away from the pass band. However, a slightly high ripple occurs between about 2570 MHz and about 2580 MHZ.

In contrast, as illustrated in FIG. 4, in the parallel arm resonator P3 in Example Embodiment 1, the waveform of the resonant frequency frp is well-formed between about 2570 MHz and about 2580 MHz, and the impedance value is sufficiently low. In addition, as illustrated in FIG. 5, in the parallel arm resonator P3 in Example Embodiment 1, the ripple which occurs in Comparative Example does not occur between about 2570 MHz and about 2580 MHZ.

FIG. 6 graph illustrating the bandpass is a characteristics of the acoustic wave filter devices in Example Embodiment 1 and Comparative Example. In FIG. 6, Example Embodiment 1 is represented by using the solid lines, and Comparative Example is represented by using the broken lines. However, when viewed by using a wide frequency band as in FIG. 6, each solid line and each broken line appear to be almost overlapping.

As described above, the pass band of the acoustic wave filter device is, for example, between about 2595 MHz and about 2722 MHz, inclusive. In this example, the resonant frequency frp of the parallel arm resonator P3 overlaps with an attenuation slope that is an inclined curve between the pass band and the attenuation pole in the lower-frequency-side block area.

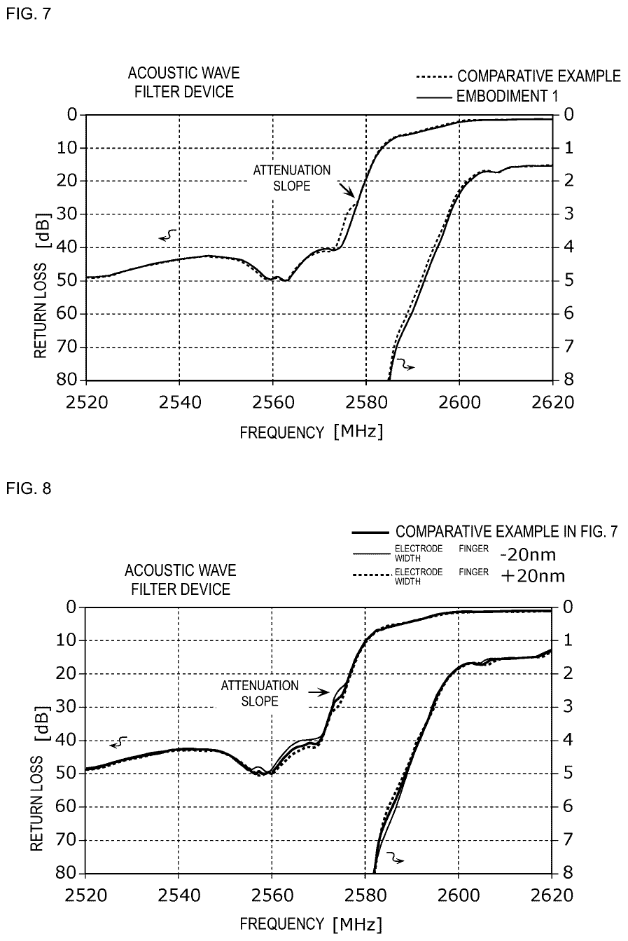

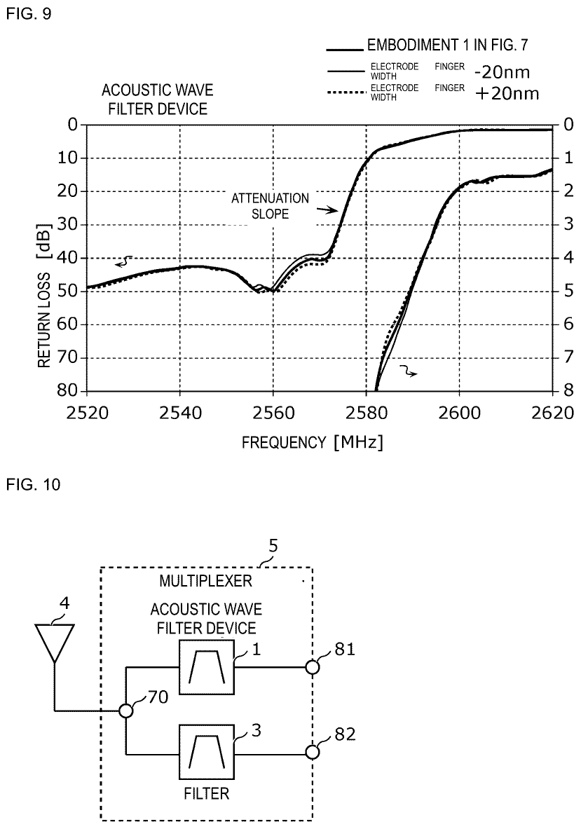

FIG. 7 is a graph in which portion of the bandpass characteristics illustrated the portion in FIG. 6 is enlarged. FIG. 7 illustrates the insertion loss on the lower-frequency side of the pass band of the acoustic wave filter device.

As illustrated in FIG. 7, in the acoustic wave filter device including the parallel arm resonator P3 in Comparative Example, stepwise protrusions occur on the attenuation slope on the lower-frequency side of the pass band. In contrast, in the acoustic wave filter device 1 including the parallel arm resonator P3 in Example Embodiment 1, the inclination of the attenuation slope is constant or substantially constant, and the insertion loss between the pass band and lower-frequency-side block area changes smoothly. It is thus possible to prevent the attenuation characteristic on the lower-frequency side of the pass band from varying largely in the acoustic wave filter device 1.

In the parallel arm resonator P3 in Example Embodiment 1, as illustrated in FIG. 5, an unwanted response between about 2850 MHz and about 2880 MHz on the higher-frequency side of the pass band approaches the pass band, and the return loss is higher. However, Example Embodiment 1 enables the unwanted response to be reduced by using the parallel arm resonators P1, P2, and P4 having the configuration in which the reflector wavelength Δ_{REF} is longer than the IDT wavelength Δ_{IDT} and the IDT-reflector gap IRGAP is shorter than about 0.5 times the reflector wavelength Δ_{REF}. Accordingly, in the acoustic wave filter device 1 in Example Embodiment 1, it is possible to prevent high loss from occurring on the higher-frequency side of the pass band.

### Other Examples of Bandpass Characteristics of Acoustic Wave Filter Device

Examples of the bandpass characteristics of the acoustic wave filter devices in a case where the electrode fingers of the IDT electrode 11 have different widths will be described.

FIG. 8 is a graph illustrating the bandpass characteristics of the acoustic wave filter device in a case where the electrode fingers 11a and 11b of the IDT electrode 11 have different widths in Comparative Example. The solid lines in FIG. 8 represent the same example as that of the acoustic wave filter device in Comparative Example illustrated in FIG. 7, the thin lines represent an example where the width of the electrode fingers 11a and 11b is about 20 nm narrower than that in Comparative Example illustrated in FIG. 7, and the broken lines represent an example where the width of the electrode fingers 11a and 11b is about 20 nm wider than that in Comparative Example illustrated in FIG. 7.

As illustrated in FIG. 8, in Comparative Example, the different widths of the electrode fingers 11a and 11b cause different locations where the stepwise protrusions occur on the attenuation slope. Accordingly, in the acoustic wave filter device in Comparative Example, for example, if there is manufacturing variations in the width dimension of the electrode fingers 11a and 11b, the attenuation characteristic on the lower-frequency side of the pass band varies largely.

FIG. 9 is a graph illustrating the bandpass characteristics of the acoustic wave filter device 1 in a case where the electrode fingers 11a and 11b of the IDT electrode 11 have different widths in Example Embodiment 1. The solid lines in FIG. 9 represent the same example as that of the acoustic wave filter device 1 in Example Embodiment 1 illustrated in FIG. 7, the thin lines represent an example where the width of the electrode fingers 11a and 11b is about 20 nm narrower than that in Example Embodiment 1 illustrated in FIG. 7, and the broken lines represent an example where the width of the electrode fingers 11a and 11b is about 20 nm wider than that in Example Embodiment 1 illustrated in FIG. 7 20 nm.

As illustrated in FIG. 9, in Example Embodiment 1, even if the electrode fingers 11a and 11b have the different widths, the stepwise protrusions do not occur on the attenuation slope, and the inclination of the attenuation slope is constant or substantially constant. Accordingly, in Example Embodiment 1, even if there is manufacturing variations in the width dimension of the electrode fingers 11a and 11b, it is possible to prevent the attenuation characteristic on the lower-frequency side of the pass band from varying largely.

### Example Embodiment 2

Example embodiment 2 of the present invention describes a multiplexer having a configuration in which a plurality of filters including the acoustic wave filter device 1 are directly or indirectly connected to a common terminal.

FIG. 10 is a circuit configuration diagram of a multiplexer 5 according to Example Embodiment 2 and a peripheral circuit thereof (an antenna 4). The multiplexer 5 illustrated in FIG. 10 includes the acoustic wave filter device 1, a remaining filter 3 different from the acoustic wave filter device 1, a common terminal 70, and input/output terminals 81 and 82.

The acoustic wave filter device 1 is the acoustic wave filter device 1 according to Example Embodiment 1. The input/output terminal 50 of the acoustic wave filter device 1 is connected to the input/output terminal 81, and the input/output terminal 60 of the acoustic wave filter device 1 is connected to the common terminal 70.

The remaining filter 3 is connected to the common terminal 70 and the input/output terminal 82. The remaining filter 3 is, for example, a ladder acoustic wave filter device including parallel arm resonators and series arm resonators but may be, for example, an LC filter or the like. The circuit configuration is not particularly limited.

A pass band of the acoustic wave filter device 1 is located on the higher-frequency side of the pass band of the remaining filter 3. That is, among the plurality of filters, at least one of one or more remaining filters 3 except the acoustic wave filter device 1 has a pass band lower than frequencies in the pass band of the acoustic wave filter device 1. It is thus possible to prevent insertion loss in the pass band of the remaining filter 3 from increasing in the multiplexer 5 including the acoustic wave filter device 1 and the remaining filter 3 having the pass band lower than that of the acoustic wave filter device 1.

Alternatively, the pass band of the acoustic wave filter device 1 is located on the lower-frequency side of the pass band of the remaining filter 3. That is, among the plurality of filters, at least one of the one or more remaining filters 3 except the acoustic wave filter device 1 has a pass band higher than the frequencies in the pass band of the acoustic wave filter device 1. It is possible to prevent insertion loss in the pass band of the remaining filter 3 from increasing in the multiplexer 5 including the acoustic wave filter device 1 and the remaining filter 3 having the pass band higher than that of the acoustic wave filter device 1.

The acoustic wave filter device 1 and the remaining filter 3 do not have to be directly connected to the common terminal 70 unlike the illustration in FIG. 10 and may also be connected to indirectly to the common terminal 70, for example, with an impedance matching circuit, a phase shifter, a circulator, or a switch element enabling two or more filters to be selected interposed therebetween. In addition, although the multiplexer 5 has the circuit configuration in which the two filters are connected to the common terminal 70 in the present example embodiment, the number of filters connected to the common terminal 70 is not limited to 2 and may be 3 or more.

An acoustic wave filter device 1 according to an example embodiment of the present invention includes the plurality of acoustic wave resonators 10. The plurality of acoustic wave resonators 10 include the series arm resonators S1 to S4 disposed on the first path rl connecting the two input/output terminals 50 and 60 and the plurality of parallel arm resonators P1 to P4 disposed between the first path rl and the ground. The plurality of parallel arm resonators P1 to P4 are provided on the piezoelectric substrate 100 and include the IDT electrode 11 and the reflectors 12, the IDT electrode 11 including the paired comb-shaped electrodes 11A and 11B facing each other, the reflectors 12 each being disposed adjacent to the IDT electrode 11 in the acoustic wave propagation direction. Each comb-shaped electrode (each of 11A and 11B) includes the plurality of electrode fingers (a corresponding one of 11a and 11b) and the busbar electrodes 11c, the plurality of electrode fingers extending in the direction that crosses the acoustic wave propagation direction, the busbar electrodes 11c each connecting one ends of the plurality of electrode fingers (a corresponding one of 11a and 11b). Each of the reflectors 12 includes the plurality of reflective electrode fingers 12a extending in the direction that crosses the acoustic wave propagation direction.

The reflector wavelength Δ_{REF} is twice the pitch of the plurality of reflective electrode fingers 12a, the IDT wavelength Δ_{IDT} is twice the pitch of the plurality of electrode fingers 11a and 11b included in the IDT electrode 11, and the IDT-reflector gap IRGAP is a center-to-center distance, in the acoustic wave propagation direction, between an electrode finger of the plurality of electrode fingers 11a and 11b that is closest to the reflector 12 and a reflective electrode finger of the plurality of reflective electrode fingers 12a that is closest to the IDT electrode 11. In this case, the following relationship is provided.

A parallel arm resonator (for example, P3) of the plurality of parallel arm resonators P1 to P4 that has the highest resonant frequency frp has a reflector wavelength Δ_{REF} that is the same or substantially the same as the IDT wavelength Δ_{IDT} and also has an IDT-reflector gap IRGAP that is about 0.5 times the reflector wavelength Δ_{REF}. Among the plurality of parallel arm resonators P1 to P4, at least one of remaining parallel arm resonators (for example, P1, P2, and P4) except the parallel arm resonator having the highest resonant frequency frp (for example, P3) has a reflector wavelength Δ_{REF} longer than the IDT wavelength Δ_{IDT} and has an IDT-reflector gap IRGAP shorter than about 0.5 times the reflector wavelength Δ_{REF}.

As described above, in the parallel arm resonator P3 having the highest resonant frequency frp, the reflector wavelength Δ_{REF} has the same or substantially the same as the IDT wavelength Δ_{IDT}, and the IDT-reflector gap IRGAP is about 0.5 times the reflector wavelength Δ_{REF}. It is thus possible to prevent the attenuation characteristic on the lower-frequency side of the pass band from varying largely in the acoustic wave filter device 1.

In the at least one of the remaining parallel arm resonators P1, P2, and P4 except the parallel arm resonator P3, the reflector wavelength Δ_{REF} is longer than the IDT wavelength Δ_{IDT}, and the IDT-reflector gap IRGAP is shorter than about 0.5 times the reflector wavelength Δ_{REF}. It is thus possible to reduce an unwanted response occurring on the higher-frequency side of the pass band. It is thus possible to prevent high loss from occurring on the higher-frequency side of the pass band.

All of the remaining parallel arm resonators P1, P2, and P4 may also have the reflector wavelength Δ_{REF} longer than the IDT wavelength Δ_{IDT}, and the IDT-reflector gap IRGAP may also be shorter than about 0.5 times the reflector wavelength Δ_{REF}.

As described above, in all of the remaining parallel arm resonators P1, P2, and P4, the reflector wavelength Δ_{REF} is longer than the IDT wavelength Δ_{IDT}, and the IDT-reflector gap IRGAP is shorter than about 0.5 times the reflector wavelength Δ_{REF}. It is thus possible to further reduce an unwanted response occurring on the higher-frequency side of the pass band. It is thus possible to prevent high loss from occurring on the higher-frequency side of the pass band.

An acoustic wave filter device 1 according to an example embodiment of the present invention includes the plurality of acoustic wave resonators 10. The plurality of acoustic wave resonators 10 include the series arm resonators S1 to S4 disposed on the first path rl connecting the two input/output terminals 50 and 60 and the plurality of parallel arm resonators P1 to P4 disposed between the first path rl and the ground. The plurality of parallel arm resonators Pl to P4 are provided on the piezoelectric substrate 100 and include the IDT electrode 11 and the reflectors 12, the IDT electrode 11 including the paired comb-shaped electrodes 11A and 11B facing each other, the reflectors 12 each being disposed adjacent to the IDT electrode 11 in the acoustic wave propagation direction. Each comb-shaped electrode (each of 11A and 11B) includes the plurality of electrode fingers (a corresponding one of 11a and 11b) and the busbar electrodes 11c, the plurality of electrode fingers extending in the direction that crosses the acoustic wave propagation direction, the busbar electrode 11c each connecting one ends of the plurality of electrode fingers (a corresponding one of 11a and 11b). Each of the reflectors 12 includes the plurality of reflective electrode fingers 12a extending in the direction that crosses the acoustic wave propagation direction.

The electrode finger pitch pi is the pitch of the plurality of electrode fingers 11a and 11b included in the IDT electrode 11, the reflective electrode finger pitch pr is the pitch of the plurality of reflective electrode fingers 12a, and the IDT-reflector gap IRGAP is a center-to-center distance, in the acoustic wave propagation direction, between an electrode finger of the plurality of electrode fingers 11a and 11b that is closest to the reflector 12 and a reflective electrode finger of the plurality of reflective electrode fingers 12a that is closest to the IDT electrode 11. In this case, the following relationship is provided.

A parallel arm resonator of the plurality of parallel arm resonators P1 to P4 that has the shortest electrode finger pitch pi (for example, P3) a reflective electrode finger pitch pr that is the same or substantially the same as the electrode finger pitch pi and also has an IDT-reflector gap IRGAP that is the same or substantially the same as the reflective electrode finger pitch pr. Among the plurality of parallel arm resonators P1 to P4, at least one of the remaining parallel arm resonators (for example, P1, P2, or P4) except the parallel arm resonator having the shortest electrode finger pitch pi (for example, P3) has a reflective electrode finger pitch pr longer than the electrode finger pitch pi and has an IDT-reflector gap IRGAP shorter than the reflective electrode finger pitch pr.

As described above, in the parallel arm resonator P3 having the shortest electrode finger pitch pi, the reflective electrode finger pitch pr is the same or substantially the same as the electrode finger pitch pi, and the IDT-reflector gap IRGAP is the same or substantially the same as the reflective electrode finger pitch pr. It is thus possible to prevent the attenuation characteristic on the lower-frequency side of the pass band from varying largely in the acoustic wave filter device 1.

In the at least one of the remaining parallel arm resonators P1, P2, and P4 except the parallel arm resonator P3, the reflective electrode finger pitch pr is longer than the electrode finger pitch pi, and the IDT-reflector gap IRGAP is shorter than the reflective electrode finger pitch pr. It is thus possible to reduce an unwanted response occurring on the higher-frequency side of the pass band. It is thus possible to prevent high loss from occurring on the higher-frequency side of the pass band.

In all of the remaining parallel arm resonators P1, P2, and P4, the reflective electrode finger pitch pr may be longer than the electrode finger pitch pi, and the IDT-reflector gap IRGAP may be shorter than the reflective electrode finger pitch pr.

As described above, in all of the remaining parallel arm resonators P1, P2, and P4, the reflective electrode finger pitch pr is longer than the electrode finger pitch pi, and the IDT-reflector gap IRGAP is shorter than the reflective electrode finger pitch pr. It is thus possible to further reduce an unwanted response occurring on the higher-frequency side of the pass band. It is thus possible to prevent high loss from occurring on the higher-frequency side of the pass band.

A multiplexer 5 according to an example embodiment of the present invention includes the plurality of filters including the acoustic wave filter device 1 described above. The respective input/output terminals 81 and 82 of the plurality of filters are directly or indirectly connected to the common terminal 70. Among the plurality of filters, at least one of the remaining one or more filters 3 except the acoustic wave filter device 1 has the pass band lower than frequencies in the pass band of the acoustic wave filter device 1.

It is thus possible to prevent insertion loss in the pass band of the remaining filter 3 from increasing in the multiplexer 5 including the acoustic wave filter device 1 and the remaining filter 3 having the pass band lower than that of the acoustic wave filter device 1.

A multiplexer 5 according to an example embodiment includes the plurality of filters including the acoustic wave filter device 1 described above. The respective input/output terminals 81 and 82 of the plurality of filters are directly or indirectly connected to the common terminal 70. Among the plurality of filters, at least one of the remaining one or more filters 3 except the acoustic wave filter device 1 has the pass band higher than the frequencies in the pass band of the acoustic wave filter device 1.

It is thus possible to prevent insertion loss in the pass band of the remaining filter 3 from increasing in the multiplexer 5 including the acoustic wave filter device 1 and the remaining filter 3 having the pass band higher than that of the acoustic wave filter device 1.

The acoustic wave filter devices and the multiplexers according to the example embodiments of the present invention have heretofore been described by using the example embodiments and the example embodiment example. However, the acoustic wave filter devices and the multiplexers of the present invention are not limited to the example embodiments above. Another example embodiment provided by combining any components in the example embodiments above, an example embodiment example obtained by applying, to the example embodiments above, a modification conceived by those skilled in the art without departing from the spirit of the present invention, and various types of equipment including the acoustic wave filter devices and the multiplexers according to example embodiments of the present invention that are built therein are also included in the present invention.

For Example Embodiment 1 above, the example where the parallel arm resonator P3 of the plurality of parallel arm resonators P1 to P4 has the highest resonant frequency frp has been described. However, the example embodiment is not limited to this. For example, one of the parallel arm resonators P1, P2, and P4 of the plurality of parallel arm resonators P1 to P4 may have the highest resonant frequency frp. In this case, it suffices that the parallel arm resonator having the highest resonant frequency frp (P1, P2, or P4) has the reflector wavelength Δ_{REF} that is the same or substantially the same as the IDT wavelength Δ_{IDT} and has the IDT-reflector gap IRGAP that is about 0.5 times the reflector wavelength Δ_{REF}. In contrast, it suffices that at least one of the remaining parallel arm resonators except the parallel arm resonator having the highest resonant frequency frp (P1, P2, or P4) has a reflector wavelength Δ_{REF} longer than the IDT wavelength Δ_{IDT} and an IDT-reflector gap IRGAP shorter than about 0.5 times the reflector wavelength Δ_{REF}.

The parallel arm resonator P3 of the plurality of parallel arm resonators P1 to P4 that has the highest resonant frequency frp does not have to be disposed closest to the common terminal 70 on the first path rl, and one of the remaining parallel arm resonators (for example, P1) except the parallel arm resonator P3 may be disposed closest to the common terminal 70 on the first path r1.

For Example Embodiment 1 above, the example where the reflector wavelength/IDT wavelength value of the parallel arm resonator P3 is compared with the reflector wavelength/IDT wavelength value of the parallel arm resonators P1, P2, and P4 has been described. However, the acoustic wave filter device 1 may further have a relationship in which the reflector wavelength/IDT wavelength value of the parallel arm resonators P1 to P4 is smaller than the reflector wavelength/IDT wavelength value of the series arm resonators S1 to S4.

For example, the acoustic wave filter device 1 may further include a circuit element such as an inductor and a capacitor.

The acoustic wave resonator according to the present invention does not have to be the surface acoustic wave resonator as in Example Embodiment 1 and may be, for example, an acoustic wave resonator using boundary acoustic waves.

As described above, the piezoelectric substrate 100 may be the substrate including a piezoelectric layer in at least portion thereof and may also have the layered structure including the piezoelectric layer. The piezoelectric substrate 100 may include, for example, a high-acoustic-velocity support substrate, a low-acoustic-velocity film, and a piezoelectric layer and may have the structure including the high-acoustic-velocity support substrate, the low-acoustic-velocity film, and the piezoelectric layer that are stacked in this order. Hereinafter, the configuration of the high-acoustic-velocity support substrate, the low-acoustic-velocity film, and the piezoelectric layer will be described.

The piezoelectric layer is made of, for example, 0° rotated Y cut X SAW propagation LiNbO₃ piezoelectric single crystal or a piezoelectric ceramic (lithium niobate single crystal or ceramic that is cut along a plane with a normal line serving as an axis rotated by θ′ in the z axis direction from a Y axis with respect to an X axis serving as the center axis and in which a surface acoustic wave propagates in the X-axis direction).

The high-acoustic-velocity support substrate is a substrate that supports the low-acoustic-velocity film, the piezoelectric layer, and the electrode 110. Further, the high-acoustic-velocity support substrate is a substrate in which the acoustic velocity of a bulk wave in the high-acoustic-velocity support substrate is higher than the acoustic velocity of an acoustic wave, that is, the surface acoustic wave propagating in the piezoelectric layer or the boundary acoustic wave. The high-acoustic-velocity support substrate confines the surface acoustic wave in a portion where the piezoelectric layer and the low-acoustic-velocity film are laminated and prevents the surface acoustic wave from leaking to a portion lower than the high-acoustic-velocity support substrate. The high-acoustic-velocity support substrate is, for example, a silicon substrate. The high-acoustic-velocity support substrate is made of, for example, any one of (1) a piezoelectric body such as aluminum nitride, aluminum oxide, silicon carbide, silicon nitride, silicon, sapphire, lithium tantalate, lithium niobate, or crystal, (2) any of various ceramics such as alumina, zirconia, cordierite, mullite, steatite, and forsterite, (3) magnesia diamond, (4) a material including any of the materials above as a main component, and (5) a material including a mixture of any of the materials above as a main component.

The low-acoustic-velocity film is a film in which the acoustic velocity of a bulk wave in the low-acoustic-velocity film is lower than the acoustic velocity of an acoustic wave propagating in the piezoelectric layer. The low-acoustic-velocity film is disposed between the piezoelectric layer and the high-acoustic-velocity support substrate. This structure and the property of energy concentration on a medium essentially having a low-velocity acoustic wave prevent the surface acoustic wave energy from leaking to the outside of an IDT electrode. The low-acoustic-velocity film is a film made of, for example, silicon dioxide (SiO) as a main component.

The layered structure described above of the piezoelectric substrate 100 enables a Q value of an acoustic wave resonator in the resonant frequency and the anti-resonant frequency to be considerably higher than that in a structure in which the piezoelectric substrate 100 is a single layer. That is, a surface acoustic wave resonator having a high Q value may be provided, and thus a filter having a low insertion loss may be provided by using the surface acoustic wave resonator.

The high-acoustic-velocity support substrate may have a structure in which a support substrate and a high-acoustic-velocity film are laminated. In the high-acoustic-velocity film, the acoustic velocity of a propagating bulk wave is higher than the acoustic velocity of an acoustic wave, that is, the surface acoustic wave propagating in the piezoelectric layer or the boundary acoustic wave. In this case, a piezoelectric body such as, for example, sapphire, lithium tantalate, lithium niobate, or the crystal, any of various ceramics such as alumina, magnesia, silicon nitride, aluminum nitride, silicon carbide, zirconia, cordierite, mullite, steatite, and forsterite, a dielectric such as glass, a semiconductor such as silicon or gallium nitride, a resin substrate, or the like may be used for the support substrate. For the high-acoustic-velocity film, various high-acoustic-velocity materials may be used, such as, for example, aluminum nitride, aluminum oxide, silicon carbide, silicon nitride, silicon oxynitride, a DLC film, and diamond, a medium including any of the materials above as a main component, and a medium including a mixture of any of the materials above as a main component.

The materials and the like of the layers exemplified in the layered structure described above of the piezoelectric substrate 100 are examples and may be changed based on, for example, a characteristic to be emphasized among required radio frequency propagation characteristics.

Example embodiments of the present invention may be widely used for communication equipment, such as a mobile phone, as an acoustic wave filter device and a multiplexer that have low loss and support multiband and multimode, for example.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave filter device comprising:
a plurality of acoustic wave resonators; wherein
each of the plurality of acoustic wave resonators includes a series arm resonator on a first path connecting two input/output terminals and a plurality of parallel arm resonators connected between the first path and ground;
each of the plurality of parallel arm resonators is provided on a piezoelectric substrate and includes an interdigital transducer (IDT) electrode including a pair of comb-shaped electrodes facing each other and a reflector adjacent to the IDT electrode in an acoustic wave propagation direction;
each of the comb-shaped electrodes of the pair of comb-shaped electrodes includes a plurality of electrode fingers extending in a direction crossing the acoustic wave propagation direction and a busbar electrode connecting ends of the plurality of electrode fingers to each other;
the reflector includes a plurality of reflective electrode fingers extending in the direction crossing the acoustic wave propagation direction, and
where a reflector wavelength is twice a pitch of the plurality of reflective electrode fingers, an IDT wavelength is twice a pitch of the plurality of electrode fingers included in the IDT electrode, and an IDT-reflector gap is a center-to-center distance, in the acoustic wave propagation direction, between an electrode finger of the plurality of electrode fingers that is closest to the reflector and a reflective electrode finger of the plurality of reflective electrode fingers that is closest to the IDT electrode, a parallel arm resonator of the plurality of parallel arm resonators that has a highest resonant frequency has a reflector wavelength the same or substantially the same as the IDT wavelength and has an IDT-reflector gap about 0.5 times the reflector wavelength; and
among the plurality of parallel arm resonators, at least one of one or more remaining parallel arm resonators except the parallel arm resonator having the highest resonant frequency has a reflector wavelength longer than the IDT wavelength and has an IDT-reflector gap shorter than about 0.5 times the reflector wavelength.

2. The acoustic wave filter device according to claim 1, wherein all of the one or more remaining parallel arm resonators have a reflector wavelength longer than the IDT wavelength and have an IDT-reflector gap that is shorter than about 0.5 times the reflector wavelength.

3. The acoustic wave filter device according to claim 1, wherein each of the plurality of parallel arm resonators includes a protective film covering the IDT electrode.

4. The acoustic wave filter device according to claim 1, wherein each of the comb-shaped electrodes includes a close-contact layer and a main electrode layer that are laminated.

5. The acoustic wave filter device according to claim 4, wherein the main electrode layer includes Al including about 1% Cu.

6. An acoustic wave filter device comprising:
a plurality of acoustic wave resonators; wherein
the plurality of acoustic wave resonators each include a series arm resonator on a first path connecting two input/output terminals and a plurality of parallel arm resonators connected between the first path and ground;
each of the plurality of parallel arm resonators is provided on a piezoelectric substrate and includes an interdigital transducer (IDT) electrode including a pair of comb-shaped electrodes facing each other and a reflector adjacent to the IDT electrode in an acoustic wave propagation direction;
each of the comb-shaped electrodes of the pair of comb-shaped electrodes includes a plurality of electrode fingers extending in a direction crossing the acoustic wave propagation direction and a busbar electrode connecting ends of the plurality of electrode fingers to each other;
the reflector includes a plurality of reflective electrode fingers extending in the direction crossing the acoustic wave propagation direction; and
where an electrode finger pitch is a pitch of the plurality of electrode fingers included in the IDT electrode, a reflective electrode finger pitch is a pitch of the plurality of reflective electrode fingers, and an IDT-reflector gap is a center-to-center distance, in the acoustic wave propagation direction, between an electrode finger of the plurality of electrode fingers that is closest to the reflector and a reflective electrode finger of the plurality of reflective electrode fingers that is closest to the IDT electrode, a parallel arm resonator of the plurality of parallel arm resonators that has a shortest electrode finger pitch has a reflective electrode finger pitch the same or substantially the same as the electrode finger pitch and has an IDT-reflector gap that is the same or substantially the same as the reflective electrode finger pitch; and
among the plurality of parallel arm resonators, at least one of one or more remaining parallel arm resonators except the parallel arm resonator having a shortest electrode finger pitch has a reflective electrode finger pitch longer than the electrode finger pitch and has an IDT-reflector gap that is shorter than the reflective electrode finger pitch.

7. The acoustic wave filter device according to claim 6, wherein all of the one or more remaining parallel arm resonators have a reflective electrode finger pitch longer than the electrode finger pitch and have an IDT-reflector gap that is shorter than the reflective electrode finger pitch.

8. The acoustic wave filter device according to claim 6, wherein each of the plurality of parallel arm resonators includes a protective film covering the IDT electrode.

9. The acoustic wave filter device according to claim 6, wherein each of the comb-shaped electrodes includes a close-contact layer and a main electrode layer that are laminated.

10. The acoustic wave filter device according to claim 9, wherein the main electrode layer includes Al including about 1% Cu.

11. A multiplexer comprising:
a plurality of filters including the acoustic wave filter device according to claim 1; wherein
an input/output terminal of each of the plurality of filters is directly or indirectly connected to a common terminal; and
among the plurality of filters, at least one of one or more remaining filters except the acoustic wave filter device has a pass band lower than a frequency in a pass band of the acoustic wave filter device.

12. The multiplexer according to claim 11, wherein all of the one or more remaining parallel arm resonators have a reflector wavelength longer than the IDT wavelength and have an IDT-reflector gap that is shorter than about 0.5 times the reflector wavelength.

13. The multiplexer according to claim 11, wherein each of the plurality of parallel arm resonators includes a protective film covering the IDT electrode.

14. The multiplexer according to claim 11, wherein each of the comb-shaped electrodes includes a close-contact layer and a main electrode layer that are laminated.

15. The multiplexer according to claim 14, wherein the main electrode layer includes Al including about 1% Cu.

16. A multiplexer comprising:
a plurality of filters including the acoustic wave filter device according to claim 1; wherein
an input/output terminal of each of the plurality of filters is directly or indirectly connected to a common terminal; and
among the plurality of filters, at least one of one or more remaining filters except the acoustic wave filter device has a pass band higher than a frequency in a pass band of the acoustic wave filter device.

17. The multiplexer according to claim 16, wherein all of the one or more remaining parallel arm resonators have a reflective electrode finger pitch longer than the electrode finger pitch and have an IDT-reflector gap that is shorter than the reflective electrode finger pitch.

18. The multiplexer according to claim 16, wherein each of the plurality of parallel arm resonators includes a protective film covering the IDT electrode.

19. The multiplexer according to claim 16, wherein each of the comb-shaped electrodes includes a close-contact layer and a main electrode layer that are laminated.

20. The multiplexer according to claim 19, wherein the main electrode layer includes Al including about 1% Cu.
